(19) United States
(12) Patent Application Publication
(10) Pub. No.: US 2026/0143587 A1
(43) Pub. Date: May 21, 2026

(54) CIRCUIT BOARD AND SEMICONDUCTOR PACKAGE INCLUDING SAME

(71) Applicant: LG INNOTEK CO., LTD., Seoul (KR)

(72) Inventors: Sae Hoon LIM, Seoul (KR); Se Ho MYEONG, Seoul (KR); Nam Gyu YUN, Seoul (KR)

(21) Appl. No.: 19/121,875

(22) PCT Filed: Oct. 19, 2023
(86) PCT No.: PCT/KR2023/016272

§ 371 Date: Apr. 17, 2025

(30) Foreign Application Priority Data
Oct. 19, 2022 (KR) 10-2022-0135293

(51) Int. Cl. H05K 1/11; H05K 1/02; H05K 1/181

(52) U.S. Cl. CPC H05K 1/111; H05K 1/0298; H05K 1/181

(57) ABSTRACT

A circuit board according to an embodiment includes an insulating layer; a first pad disposed on the insulating layer; and, a protective layer disposed on the insulating layer and including a first open region vertically overlapping the first pad, wherein a width of the first open region in a horizontal direction is smaller than a width of the first pad in the horizontal direction, and wherein an inner wall forming the first open region of the protective layer has a first inner wall and a second inner wall having a step along the horizontal direction.

### TECHNICAL FIELD

An embodiment relates to a circuit board and a semiconductor package including the same.

### BACKGROUND ART

In general, a printed circuit board (PCB) is a laminated structure in which insulating layers and conductor layers are alternately laminated, and the conductor layers can be formed into a circuit pattern by patterning.

A printed circuit board such as above is equipped with a solder resist (SR) that protects a circuit formed at an outermost side of the laminated structure, prevents oxidation of the conductor layer, and also acts as an insulator when electrically connecting to a chip mounted on the printed circuit board or other substrate.

A typical solder resist forms an opening region (SRO: Solder Resist Opening) that becomes an electrical connection path by combining connecting means such as solder or bumps, and the opening region of the solder resist requires a larger number of opening regions as the I/O (Input/Output) performance improves as the printed circuit board becomes high-performance and densification, thereby requiring a small bump pitch of the opening region. At this time, the bump pitch of the opening region of the solder resist means a center distance between adjacent opening regions.

Meanwhile, the opening region (SRO) of the solder resist includes a SMD (Solder Mask Defined type) type and a NSMD (Non-Solder Mask Defined Type) type.

The SMD type is characterized in that a width of the opening region (SRO) is smaller than a width of a pad exposed through the opening region (SRO), and thus, at least a part of an upper surface of the pad in the SMD type is covered by the solder resist.

In addition, the NSMD type is characterized in that a width of the opening region (SRO) is larger than a width of a pad exposed through the opening region (SRO), and thus, in the NSMD type, the solder resist is disposed to be spaced apart from the pad at a predetermined distance, and thus has a structure in which both an upper surface and a side surface of the pad are exposed.

However, in a case of the SMD type, after a semiconductor package is combined with the main board, there is a problem that the solder ball is separated from the pad exposed through the opening region (SRO) during a solder ball joint reliability test for a bonding strength of the solder ball.

In addition, a post bump may be disposed in the open region of the solder resist of the SMD type. However, in a conventional semiconductor package, when an impact occurs from an outside, the impact may be transmitted to the post bump as a whole, and there is a problem that cracks occur in the post bump as a result.

### DISCLOSURE

### Technical Problem

An embodiment provides a circuit board having a novel structure and a semiconductor package including the same.

In addition, the embodiment provides a circuit board having improved mechanical reliability and physical reliability and a semiconductor package including the same.

In addition, the embodiment provides a circuit board including a protective layer having an open region of a novel design and a semiconductor package including the same.

Technical problems to be solved by the proposed embodiments are not limited to the above-mentioned technical problems, and other technical problems not mentioned may be clearly understood by those skilled in the art to which the embodiments proposed from the following descriptions belong.

### Technical Solution

A circuit board according to an embodiment comprises an insulating layer; a first pad disposed on the insulating layer; and, a protective layer disposed on the insulating layer and including a first open region vertically overlapping the first pad, wherein a width of the first open region in a horizontal direction is smaller than a width of the first pad in the horizontal direction, and an inner wall forming the first open region of the protective layer has a first inner wall and a second inner wall having a step along the horizontal direction.

In addition, the first open region of the protective layer includes a first part forming the first inner wall; and a second part protruding from the first part toward a side surface of the first pad and forming the second inner wall.

In addition, the second part of the first open region includes a plurality of sub-parts protruding from each other at positions spaced apart from each other in a direction away from the first part.

In addition, a planar shape of the second part has a circular or oval shape.

In addition, a planar shape of the first part has at least one shape among a circular, oval, square, triangular, and polygonal shape.

In addition, a planar shape of the first part and a planar shape of the second part have different planar shapes.

In addition, the first inner wall and the second inner wall do not vertically overlap with an edge of an upper surface of the first pad.

In addition, the circuit board further comprises a first bump disposed on a first pad vertically overlapping the first open region, and wherein a lower surface of the first bump has a planar shape corresponding to a planar shape of the first open region.

In addition, a width in the horizontal direction of a region having a maximum width in the first open region satisfies a range of 70% to 90% of the width of the first pad in the horizontal direction.

In addition, a width of the first part of the first open region in the horizontal direction satisfies a range of 30% to 70% of the width of the first pad in the horizontal direction, and a width of the second part of the first open region in the horizontal direction satisfies a range of 5% to 30% of the width of the first pad in the horizontal direction.

In addition, the circuit board further comprises a second pad spaced apart from the first pad in a horizontal direction, and the protective layer further includes a second open region vertically overlapping the second pad, and a planar shape of the second open region is different from a planar shape of the first open region.

In addition, a width in the horizontal direction of the second pad is smaller than a width in the horizontal direction of the first pad, and a width in the horizontal direction of the second open region is smaller than a width in the horizontal direction of the second pad.

In addition, an inner wall of the first open region has a step in a horizontal direction, and an inner wall of the second open region does not have a step in a horizontal direction.

Meanwhile, a circuit board according to an embodiment comprises: an insulating layer; a first pad disposed on the insulating layer; a second pad disposed on the insulating layer and spaced apart from the first pad in a horizontal direction; and a protective layer disposed on the insulating layer and including a first open region vertically overlapping with the first pad and a second open region vertically overlapping with the second pad, and a planar shape of the second open region is different from a planar shape of the first open region.

In addition, a width of the second pad in a horizontal direction is smaller than a width of the first pad in a horizontal direction, and a width of the second open region in a horizontal direction is smaller than a width of the second pad in a horizontal direction.

In addition, an inner wall of the first open region has a step in a horizontal direction, and an inner wall of the second open region does not have a step in a horizontal direction.

Meanwhile, a semiconductor package according to an embodiment comprises: an insulating layer; a first circuit layer disposed on the insulating layer and including a first pad; a protective layer disposed on the first insulating layer and including a first open region vertically overlapping with the first pad; a first bump disposed on the first pad vertically overlapping with the first open region; a first connection portion disposed on the first bump; and a first semiconductor device or a first external substrate coupled on the first connection portion, wherein a width in a horizontal direction of the first open region is smaller than a width in a horizontal direction of the first pad, and the first open region of the protective layer includes a first inner wall and a second inner wall having a step along the horizontal direction, wherein the second inner wall further protrudes from the first inner wall toward a side surface of the first pad.

### Advantageous Effects

A circuit board according to an embodiment comprises: a first insulating layer; a first circuit layer disposed on the first insulating layer and including a first pad; a first protective layer disposed on the first insulating layer and including a first open region vertically overlapping the first pad, wherein a width in the horizontal direction of the first open region is smaller than a width in the horizontal direction of the first pad, and the first open region of the first protective layer includes a first part vertically overlapping an upper surface of the first pad; and a second part connected to the first part and protruding from the first part in a direction toward a side surface of the first pad.

In addition, the second part of the first open region includes a plurality of sub-parts protruding from each other at positions spaced apart from each other in a direction away from the first part.

In addition, the first open region of the first protective layer includes a first inner wall corresponding to the first part and a second inner wall corresponding to the second part, and the first inner wall and the second inner wall have a step in the horizontal direction.

In addition, a planar shape of the second part has a circular or oval shape.

In addition, a planar shape of the first part has at least one shape among a circular, oval, square, triangular, and polygonal shape.

In addition, the first inner wall and the second inner wall do not vertically overlap with an edge of an upper surface of the first pad.

In addition, the circuit board further comprises a first bump disposed on a first pad vertically overlapping the first open region, and wherein a lower surface of the first bump has a planar shape corresponding to a planar shape of the first open region.

In addition, a width in the horizontal direction of a region having a maximum width in the first open region satisfies a range of 70% to 90% of the width of the first pad in the horizontal direction.

In addition, a width of the first part of the first open region in the horizontal direction satisfies a range of 30% to 70% of the width of the first pad in the horizontal direction, and a width of the second part of the first open region in the horizontal direction satisfies a range of 5% to 30% of the width of the first pad in the horizontal direction.

In addition, the circuit board further comprises a second pad spaced apart from the first pad in a horizontal direction, and the protective layer further includes a second open region vertically overlapping the second pad, and a planar shape of the second open region is different from a planar shape of the first open region.

In addition, a width in the horizontal direction of the second pad is smaller than a width in the horizontal direction of the first pad, and a width in the horizontal direction of the second open region is smaller than a width in the horizontal direction of the second pad.

In addition, an inner wall of the first open region has a step in a horizontal direction, and an inner wall of the second open region does not have a step in a horizontal direction.

Meanwhile, a circuit board according to an embodiment comprises: an insulating layer; a first pad disposed on the insulating layer; a second pad disposed on the insulating layer and spaced apart from the first pad in a horizontal direction; and a protective layer disposed on the insulating layer and including a first open region vertically overlapping with the first pad and a second open region vertically overlapping with the second pad, and a planar shape of the second open region is different from a planar shape of the first open region.

In addition, a width of the second pad in a horizontal direction is smaller than a width of the first pad in a horizontal direction, and a width of the second open region in a horizontal direction is smaller than a width of the second pad in a horizontal direction.

In addition, an inner wall of the first open region has a step in a horizontal direction, and an inner wall of the second open region does not have a step in a horizontal direction.

Meanwhile, a semiconductor package according to an embodiment comprises: an insulating layer; a first circuit layer disposed on the insulating layer and including a first pad; a protective layer disposed on the first insulating layer and including a first open region vertically overlapping with the first pad; a first bump disposed on the first pad vertically overlapping with the first open region; a first connection portion disposed on the first bump; and a first semiconductor device or a first external substrate coupled on the first connection portion, wherein a width in the horizontal direction of the first open region is smaller than a width in the horizontal direction of the first pad, and the first open region of the first protective layer includes a first part vertically overlapping an upper surface of the first pad; and a second part connected to the first part and protruding from the first part in a direction toward a side surface of the first pad, and wherein the inner wall of the first part of the first open region and the inner wall of the second part have a step in the horizontal direction.

In addition, the semiconductor package further comprises a second insulating layer disposed under the first insulating layer; a third pad disposed under the second insulating layer; and a second protective layer including a third open region disposed under the second insulating layer and vertically overlapping the third pad, wherein a planar shape of the third open region corresponds to a planar shape of the first open region.

In addition, the semiconductor package further comprises a second connection portion disposed under the third pad; and a second semiconductor device or a second external substrate disposed under the second connection portion.

### DESCRIPTION OF DRAWINGS

FIG. 1 is a cross-sectional view showing a circuit board according to a first embodiment.

FIG. 2 is a cross-sectional view showing a circuit board according to a second embodiment.

FIG. 3 is a plan view showing a state in which the first bump is removed from the circuit board of FIG. 2.

FIG. 4 is a plan view showing a state in which the first bump is disposed from the circuit board of FIG. 2.

FIG. 5a and FIG. 5b are drawings for explaining a first open region of a first protective layer according to an embodiment.

FIG. 6(A) and (B) are drawings for explaining a second open region of a first protective layer according to an embodiment.

FIG. 7 is an enlarged view of a first open region provided on a first-first pad of an embodiment.

FIG. 8 is an enlarged view of a first open region provided on a first-second pad of an embodiment.

FIG. 9 is a modified example of a first open region according to an embodiment.

FIG. 9 is a modified example of a first open region according to an embodiment.

FIG. 10 is a drawing showing a semiconductor package according to a first embodiment.

FIG. 11 is a drawing showing a semiconductor package according to a second embodiment.

FIG. 12 is a drawing showing a semiconductor package according to a third embodiment.

FIG. 13 is a drawing showing a semiconductor package according to a fourth embodiment.

### BEST MODE

Hereinafter, embodiments will be described in detail with reference to the accompanying drawings.

However, the spirit and scope of the present invention is not limited to a part of the embodiments described, and may be implemented in various other forms, and within the spirit and scope of the present invention, one or more of the elements of the embodiments may be selectively combined and redisposed.

In addition, unless expressly otherwise defined and described, the terms used in the embodiments of the present invention (including technical and scientific terms) may be construed the same meaning as commonly understood by one of ordinary skill in the art to which this invention belongs, and the terms such as those defined in commonly used dictionaries may be interpreted as having a meaning that is consistent with their meaning in the context of the relevant art. Further, the terms used in the embodiments of the present invention are for describing the embodiments and are not intended to limit the present invention.

In this specification, the singular forms may also include the plural forms unless specifically stated in the phrase, and may include at least one of all combinations that may be combined in A, B, and C when described in “at least one (or more) of A (and), B, and C”. Further, in describing the elements of the embodiments of the present invention, the terms such as first, second, A, B, (a), and (b) may be used.

These terms are only used to distinguish the elements from other elements, and the terms are not limited to the essence, order, or order of the elements. In addition, when an element is described as being “connected”, “coupled”, or “connected” to another element, it may include not only when the element is directly “connected” to, “coupled” to, or “connected” to other elements, but also when the element is “connected”, “coupled”, or “connected” by another element between the element and other elements.

Further, when described as being formed or disposed “on (over)” or “under (below)” of each element, the “on (over)” or “under (below)” may include not only when two elements are directly connected to each other, but also when one or more other elements are formed or disposed between two elements. Furthermore, when expressed as “on (over)” or “under (below)”, it may include not only the upper direction but also the lower direction based on one element.

### ELECTRONIC DEVICE

Before describing the embodiment, an electronic device to which the semiconductor package of the embodiment is applied will be briefly described. The electronic device includes a main board (not shown). The main board may be physically and/or electrically connected to various components. For example, the main board may be connected to the semiconductor package of the embodiment. Various semiconductor devices may be mounted on the semiconductor package.

The semiconductor device may include an active device and/or a passive device. The active device may be a semiconductor chip in the form of an integrated circuit (IC) in which hundreds to millions of devices are integrated in one semiconductor device. The semiconductor device may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor and a microcontroller, or an analog-digital converter, an application-specific IC (ASIC), or the like, or a chip set comprising a specific combination of those listed so far.

The memory chip may be a stack memory such as HBM. The memory chip may also include a memory chip such as volatile memory (e.g., DRAM), non-volatile memory (e.g., ROM), flash memory, and the like.

On the other hand, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package) and SIP (System in Package), but is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the embodiment is not limited thereto, and may be any other electronic device that processes data in addition to these.

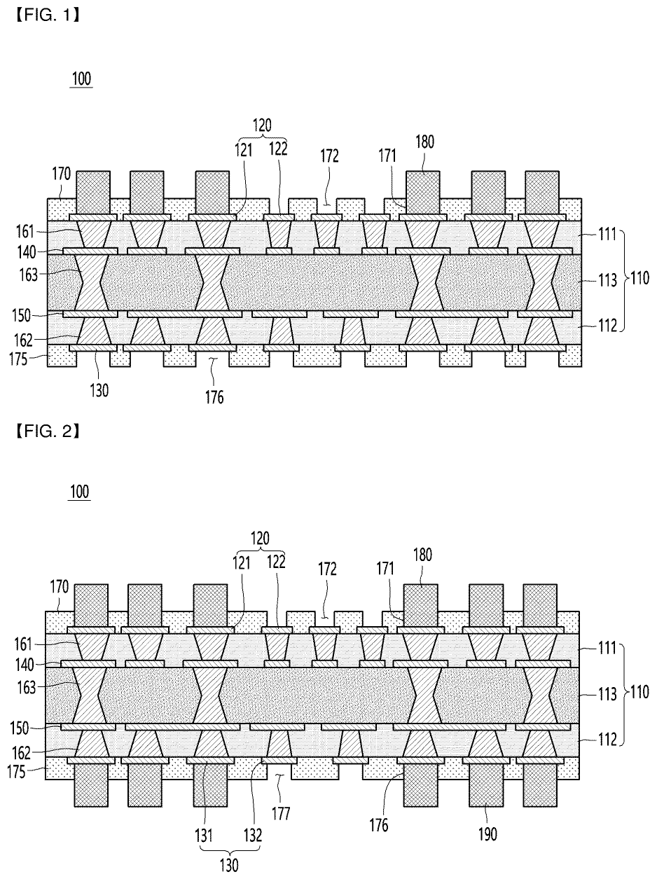

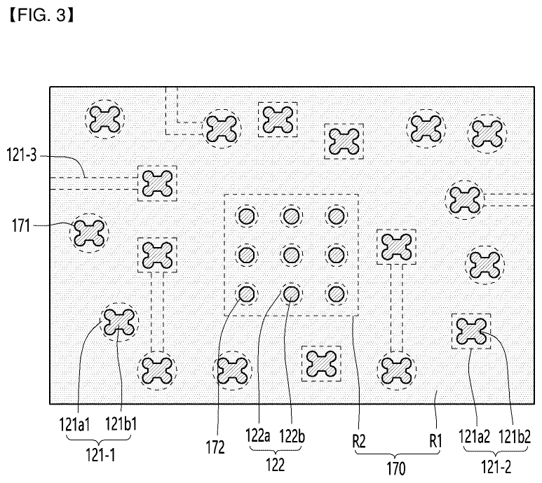

FIG. 1 is a cross-sectional view showing a circuit board according to a first embodiment, and FIG. 2 is a cross-sectional view showing a circuit board according to a second embodiment.

Comparing FIG. 1 and FIG. 2, the circuit board may include a bump for bonding with a semiconductor device and/or an external substrate. At this time, in FIG. 1, the bump may be disposed only on one side of the circuit board.

According to a first embodiment of FIG. 1, the semiconductor device and/or the external substrate on one side of the circuit board may be electrically bonded through the bump, and the semiconductor device and/or the external substrate on the other side of the circuit board may be electrically bonded through a connection member such as solder without a bump.

According to the second embodiment of FIG. 2, the semiconductor device and/or the external substrate on each of one side and the other side of the circuit board may be electrically bonded through the bump.

Hereinafter, an overall structure of the circuit board according to the embodiment will be described with reference to FIG. 2.

Referring to FIG. 2, the circuit board 100 may be coupled to at least one semiconductor device. Also, the circuit board 100 of the embodiment may be coupled to an external substrate.

In one embodiment, the external substrate may mean a substrate provided in an electronic device. For example, the external substrate may mean a main board of an electronic device. For example, the main board may mean a motherboard of an electronic device.

In another embodiment, the external substrate may mean a separate package. For example, when the circuit board is applied to a POP (Package On Package) structure, the external substrate may be a package substrate to which a separate semiconductor device is coupled. For example, the separate semiconductor device may mean a memory device, and the package substrate may be a memory substrate including the memory device, or an interposer connecting the memory substrate and the circuit board.

In addition, the semiconductor device mounted on the circuit board 100 may be one, or alternatively, may be two or more. For example, one processor chip may be mounted on the circuit board 100. For example, at least two processor chips having different functions may be mounted on the circuit board 100. For example, one processor chip and one memory chip may be mounted on the circuit board 100. For example, at least two processor chips having different functions and at least one memory chip may be mounted on the circuit board 100.

The circuit board 100 may include an insulating layer 110.

The insulating layer 110 may have a plurality of laminated structures. For example, as shown in the drawing, the insulating layer 110 may have a three-layer structure, but is not limited thereto.

At this time, the circuit board 100 of the embodiment may be a core board. For example, the circuit board 100 may include a core layer. For example, the insulating layer 110 of the circuit board 100 of the embodiment may include a third insulating layer 113 corresponding to the core layer.

For example, the circuit board 100 may have a structure in which a plurality of insulating layers having mutually symmetrical structures are laminated on upper and lower portions of the third insulating layer 113 based on the third insulating layer 113. However, the embodiment is not limited thereto. For example, a plurality of insulating layers having mutually asymmetrical structures may be disposed on the upper and lower portions of the third insulating layer 113 based on the third insulating layer 113.

Hereinafter, the circuit board 100 of the embodiment is described as a core board, and accordingly, the third insulating layer 113 is a core layer. However, the embodiment is not limited thereto. For example, the circuit board 100 of the embodiment may be a coreless board that does not include a core layer. Structural features of the circuit board 100 of the embodiment are in a circuit layer of an outermost layer of the circuit board 100 and bumps disposed on a circuit layer. Hereinafter, a structure of the circuit layer and bump of an outermost layer of the circuit board 100 of the embodiment will be described.

Accordingly, the structure of the circuit layer 120 and 130 and bump 180 and 190 of the outermost layer of the circuit board 100 described below can be applied to the core board, and differently, can be applied to the coreless board.

Furthermore, one of the circuit layers 120 and 130 of the outermost layer can have a structure embedded in the insulating layer 110. For example, the circuit board of the embodiment can have an ETS (Embedded Trace Substrate) structure. In addition, the bump 180 and 190 of the embodiment can be disposed on the circuit layer 120 and 130 of the outermost layer having the ETS structure.

The insulating layer 110 can include a first insulating layer 111 which is a first outermost insulating layer. For example, the first insulating layer 111 may refer to an insulating layer disposed at an uppermost side among the plurality of insulating layers. In addition, the insulating layer 110 may include a second insulating layer 112 which is a second outermost insulating layer. For example, the second insulating layer 112 may refer to an insulating layer disposed at a lowermost side among the plurality of insulating layers.

In addition, the insulating layer 110 may include a third insulating layer 113 disposed between the first insulating layer 111 and the second insulating layer 112. The third insulating layer 113 may be an inner insulating layer.

The third insulating layer 113 may refer to an inner insulating layer disposed at an inner layer among the plurality of insulating layers of the circuit board 100.

At this time, the third insulating layer 113 is illustrated as having a single-layer structure in the drawing, but is not limited thereto. For example, the third insulating layer 113 may have a multilayer structure. For example, the circuit board 100 may have a layer structure of four or more layers. At this time, the third insulating layer 113 corresponding to the inner insulating layer of the circuit board 100 may have a multiple layer structure based on a total number of layers of the circuit board 100. When the third insulating layer 113 has a multiple layer structure, the multiple layers of the third insulating layer 113 may include different insulating materials, but are not limited thereto.

The first insulating layer 111 may be disposed on the third insulating layer 113. For example, the first insulating layer 111 may be disposed on an upper surface of the third insulating layer 113.

The first insulating layer 111 may provide a mounting region where a chip is mounted, or a bonding region where an external substrate is bonded.

The second insulating layer 112 may be disposed on a lower surface of the third insulating layer 113. The second insulating layer 112 may refer to a second outermost insulating layer in the insulating layer 110 of the circuit board 100. For example, the second insulating layer 112 may refer to the insulating layer disposed at a lowermost side in the insulating layer 110 of the circuit board 100.

The first insulating layer 111 and the second insulating layer 112 may be rigid or flexible. For example, the first insulating layer 111 and the second insulating layer 112 may include glass or plastic. In detail, the first insulating layer 111 and the second insulating layer 112 may include chemically strengthened/semi-strengthened glass such as soda lime glass or aluminosilicate glass. Alternatively, the first insulating layer 111 and the second insulating layer 112 may include a strengthened or flexible plastic such as polyimide (PI), polyethylene terephthalate (PET), propylene glycol (PPG), or polycarbonate (PC). Alternatively, the first insulating layer 111 and the second insulating layer 112 may include sapphire.

In addition, the first insulating layer 111 and the second insulating layer 112 may include an optically isotropic film. For example, the first insulating layer 111 and the second insulating layer 112 may include COC (Cyclic Olefin Copolymer), COP (Cyclic Olefin Polymer), optically isotropic polycarbonate (PC), or optically isotropic polymethyl methacrylate (PMMA).

In addition, the first insulating layer 111 and the second insulating layer 112 may be formed of an insulating material including an inorganic filler and an insulating resin. For example, the first insulating layer 111 and the second insulating layer 112 may include a structure in which an inorganic filler such as silica or alumina is dispersed in a thermosetting resin such as an epoxy resin or a thermoplastic resin such as a polyimide. For example, the first insulating layer 111 and the second insulating layer 112 may include ABF (Ajinomoto Build-up Film), FR-4, BT (Bismaleimide Triazine), PID (Photo Imageable Dielectric resin), BT, etc.

In addition, the first insulating layer 111 and the second insulating layer 112 may be bent while having a partially curved surface. That is, the first insulating layer 111 and the second insulating layer 112 may be bent while having a partially flat surface and a partially curved surface. In detail, the first insulating layer 111 and the second insulating layer 112 may be bent while having a curved surface at an end or may be bent or curved while having a surface including a random curvature.

Each of the first insulating layer 111 and the second insulating layer 112 may have a thickness in a range of 10 μm to 60 μm. Preferably, each of the first insulating layer 111 and the second insulating layer 112 may have a thickness in the range of 12 μm to 50 μm. More preferably, each of the first insulating layer 111 and the second insulating layer 112 may have a thickness in a range of 15 μm to 40 μm.

If a thickness of the first insulating layer 111 or the second insulating layer 112 is smaller than 10 μm, a circuit layer included in the circuit board 100 may not be stably protected.

In addition, if the thickness of the first insulating layer 111 or the second insulating layer 112 exceeds 60 μm, the thickness of the circuit board 100 may increase, and thereby the thickness of the semiconductor package may increase. In addition, if the thickness of the first insulating layer 111 or the second insulating layer 112 exceeds 60 μm, a thickness of the circuit layer and a thickness of the through electrode may increase accordingly. In addition, if the thickness of the circuit layer and the thickness of the through electrode increase, it may be difficult to implement miniaturization, which may decrease the circuit integration, and the signal transmission distance may increase, which may increase signal transmission loss.

The circuit board 100 of the embodiment includes a circuit layer disposed on the insulating layer 110.

For example, the circuit board 100 may include a first circuit layer 120 disposed on an upper surface of the first insulating layer 111.

For example, the circuit board 100 may include a second circuit layer 130 disposed on a lower surface of the second insulating layer 112.

In addition, the circuit board 100 may include a third circuit layer 140 disposed between a lower surface of the first insulating layer 111 and an upper surface of the third insulating layer 113.

For example, the circuit board 100 may include a fourth circuit layer 150 disposed between an upper surface of the second insulating layer 112 and a lower surface of the third insulating layer 113.

The first circuit layer 120, the second circuit layer 130, the third circuit layer 140, and the fourth circuit layer 150 may be manufactured using conventional manufacturing processes of the printed circuit board such as an additive process, a subtractive process, a modified semi-additive process (MSAP), and a semi-additive process (SAP), and a detailed description thereof will be omitted herein.

The first circuit layer 120 may refer to a circuit layer disposed at a first outermost layer of the circuit board 100. In addition, the second circuit layer 130 may mean a circuit layer disposed at a second outermost layer of the circuit board 100.

The first circuit layer 120 may have a structure protruding above the upper surface of the first insulating layer 111. In addition, the second circuit layer 130 may have a structure protruding below the lower surface of the second insulating layer 112. However, the embodiment is not limited thereto. For example, when the circuit board 100 of the embodiment has an ETS structure, either of the first circuit layer 120 and the second circuit layer 130 may have a structure embedded within a surface of the insulating layer.

The first circuit layer 120 may be divided into a plurality of circuit patterns according to function.

For example, the first circuit layer 120 may include a plurality of pads.

For example, the first circuit layer 120 may include a first pad 121 and a second pad 122. In addition, the first circuit layer 120 may include a trace 121-3. The trace 121-3 may not be an essential component.

For example, the circuit layer disposed at an uppermost side of the circuit board in one embodiment may include a trace 121-3, and one of the first pad 121 and the second pad 122 may be electrically connected to another one of the first pad 121 and the second pad 122through the trace 121-3.

In another embodiment, the circuit layer disposed at an uppermost side of the circuit board may not have a trace 121-3. In this case, the first pad 121 and the second pad 122 may not be directly connected to each other on the first insulating layer 111. For example, the first pad 121 and the second pad 122 may be connected to a first through electrode 161, and may be electrically connected to each other through the through electrode.

The first pad 121 may be provided in a plurality of numbers. Preferably, the first pad 121 may be provided in plurality of numbers at positions physically spaced from each other.

The second pad 122 may be provided in a plurality of numbers. Preferably, the second pad 122 may be provided a plurality of numbers at positions physically spaced from each other.

In one embodiment, the first pad 121 may function as a pad for electrically coupling with an external substrate (e.g., an interposer or other package substrate) on the circuit board 100. In another embodiment, the first pad 121 may function as a pad for electrically coupling with a semiconductor device.

The second pad 122 may function as a pad for electrically coupling with a semiconductor device.

In addition, the first circuit layer 120 may include a trace connected to at least one of the first pad 121 and the second pad 122.

The first pad 121 and the second pad 122 may have different widths. For example, planar areas of the first pad 121 and the second pad 122 may be different from each other. Here, the planar area may mean an area of an upper surface of each pad.

In one embodiment, each of the first pad 121 and the second pad 122 may be pads electrically coupled to a semiconductor device. At this time, a width of a terminal provided in the semiconductor device coupled to the first pad 121 and/or a spacing between the plurality of terminals may be different from a width of a terminal provided in the semiconductor device coupled to the second pad 122 and/or a spacing between the plurality of terminals. Preferably, in this case, the width of the terminal provided in the semiconductor device coupled to the first pad 121 and/or the spacing between the plurality of terminals may be larger than the width of the terminal provided in the semiconductor device coupled to the second pad 122 and/or the spacing between the plurality of terminals.

In another embodiment, the first pad 121 may be a pad electrically coupled to an external substrate, and the second pad 122 may be a pad electrically coupled to a semiconductor device. At this time, a width of an external pad provided in the external substrate coupled to the first pad 121 and/or a spacing between the plurality of external pads may be different from a width of a terminal provided in the semiconductor device coupled to the second pad 122 and/or a spacing between the plurality of terminals. Preferably, the width of the external pad provided in the external substrate coupled to the first pad 121 and/or the spacing between the plurality of external pads may be greater than the width of the terminal provided in the semiconductor device coupled to the second pad 122 and/or the spacing between the plurality of terminals.

Accordingly, a planar area of the first pad 121 may be greater than a planar area of the second pad 122. For example, the planar area of the first pad 121 may be 1.2 times or more the planar area of the second pad 122. For example, the planar area of the first pad 121 may be 1.5 times or more the planar area of the second pad 122. For example, the planar area of the first pad 121 may be 2 times or more the planar area of the second pad 122.

Specifically, the planar area of the first pad 121 may have a range of 1.2 to 5 times the planar area of the second pad 122. Preferably, the planar area of the first pad 121 may have a range of 1.5 to 4 times the planar area of the second pad 122. More preferably, the planar area of the first pad 121 may have a range of 2 to 3.5 times the planar area of the second pad 122.

If the planar area of the first pad 121 is less than 1.2 times the planar area of the second pad 122, a semiconductor device or an external substrate may not be stably bonded to the first pad 121. In addition, if the planar area of the first pad 121 is less than 1.2 times the planar area of the second pad 122, the heat dissipation performance of the circuit board and semiconductor package, which is improved in proportion to the planar area of the first pad 121, may deteriorate. For example, if the planar area of the first pad 121 is less than 1.2 times the planar area of the second pad 122, the heat dissipation characteristics of the semiconductor device or the external substrate mounted on the circuit board 100 may deteriorate, thereby decreasing an operating speed of the semiconductor device or deteriorating the operating reliability.

On the other hand, if the planar area of the first pad 121 exceeds 5 times the planar area of the second pad 122, a time required to form the first pad 121 may increase, and thus the product yield of the circuit board may decrease. In addition, if the planar area of the first pad 121 exceeds five times the planar area of the second pad 122, the flatness of the first pad 121 may deteriorate. For example, if the planar area of the first pad 121 exceeds five times the planar area of the second pad 122, a height difference between regions of the upper surface of the first pad 121 may increase, and further, the flatness of the first bump 181 disposed on the first pad 121 may deteriorate. In addition, if the flatness of the first pad 121 or the first bump 181 deteriorates or the height difference between regions increases, a process of adjusting the flatness of the first pad 121 is required, and a manufacturing process may become complicated accordingly. In addition, if the planar area of the first pad 121 exceeds five times the planar area of the second pad 122, a grinding process for adjusting the flatness of the first bump 181 disposed on the first pad 121 must be performed, or the time for performing the grinding process may increase. In addition, if the planar area of the first pad 121 exceeds five times the planar area of the second pad 122, the circuit integration by the first pad 121 may be reduced, and thus a volume of the circuit board and semiconductor package may increase.

Meanwhile, the planar area may also be expressed as a width in the horizontal direction. For example, a width in the horizontal direction of the first pad 121 may be larger than the width in the horizontal direction of the second pad 122. At this time, the first pad 121 and the second pad 122 may have a circular shape, and the width in the horizontal direction may mean a diameter of each of the first pad 121 and the second pad 122 of the circular shape. At this time, the first pad 121 and the second pad 122 may have an oval shape, and the width in the horizontal direction may mean a diameter of each of the first pad 121 and the second pad 122 of the circular shape in a long-axis direction or a short-axis direction. In addition, the first pad 122 and the second pad 122 may have a square shape, and a width in the horizontal direction may mean any one of a horizontal distance in a width direction, a horizontal distance in a length direction, and a horizontal distance in a diagonal direction of each of the first pad 121 and the second pad 122 of the square shape.

For example, the second circuit layer 130 may include a third pad 131 and a fourth pad 132. At this time, the drawing illustrates that the second circuit layer 130 includes only the third pad 131 and the fourth pad 132, but is not limited thereto.

The third pad 131 may be provided in a plurality of numbers. Preferably, the third pad 131 may be provided in a plurality of numbers at positions physically spaced from each other.

The fourth pad 132 may be provided in a plurality of numbers. Preferably, the fourth pad 132 may be provided in a plurality of numbers at positions physically spaced from each other.

Meanwhile, the third pad 131 of the second circuit layer 130 may be a pad electrically coupled to an external substrate or a pad electrically coupled to a semiconductor device. In addition, the fourth pad 132 may be a pad electrically coupled to a semiconductor device.

At this time, the third pad 131 may have a structure corresponding to a structure of the first pad 121, and the fourth pad 132 may have a structure corresponding to a structure of the second pad 122. Accordingly, a detailed description of the third pad 131 and the fourth pad 132 will be omitted.

The first circuit layer 120, the second circuit layer 130, the third circuit layer 140, and the fourth circuit layer 150 may be formed of at least one metal material selected from gold (Au), silver (Ag), platinum (Pt), titanium (Ti), tin (Sn), copper (Cu), and zinc (Zn). In addition, the first circuit layer 120, the second circuit layer 130, the third circuit layer 140, and the fourth circuit layer 150 may be formed of a paste or solder paste including at least one metal material selected from gold (Au), silver (Ag), platinum (Pt), titanium (Ti), tin (Sn), copper (Cu), and zinc (Zn) having excellent bonding strength. Preferably, the first circuit layer 120, the second circuit layer 130, the third circuit layer 140, and the fourth circuit layer 150 may be formed of copper (Cu) which is relatively inexpensive.

Meanwhile, the first circuit layer 120 and the second circuit layer 130 may have a thickness in a range of 5 μm to 20 μm. For example, the first circuit layer 120 and the second circuit layer 130 may have a thickness in a range of 6 μm to 17 μm. The first circuit layer 120 and the second circuit layer 130 may have a thickness in a range of 7 μm to 13 μm. If the thickness of the first circuit layer 120 and the second circuit layer 130 is smaller than 5 μm, a resistance may increase. If the thickness of the first circuit layer 120 and the second circuit layer 130 exceeds 20 μm, it is difficult to miniaturize the circuit, and thus the circuit integration may decrease.

Meanwhile, the circuit board may include a through electrode penetrating at least a portion of the region of the insulating layer 110.

For example, a first through electrode 161 may be provided in the first insulating layer 111. For example, a second through electrode 162 may be provided in the second insulating layer 112. For example, a third through electrode 163 may be provided in the third insulating layer 113.

The first through electrode 161 may electrically connect the first circuit layer 120 and the third circuit layer 140 along a vertical direction.

The second through electrode 162 may electrically connect the second circuit layer 130 and the fourth circuit layer 150 along a vertical direction.

The third through electrode 163 may electrically connect the third circuit layer 140 and the fourth circuit layer 150 along a vertical direction.

The first through electrodes 161 may be provided in a plurality of numbers while being spaced apart from each other along a horizontal direction. At least one of the first through electrodes 161 may be vertically overlapped with the first pad 121. In addition, at least another one of the first through electrodes 161 may be vertically overlapped with the second pad 122.

At this time, a first through electrode 161 vertically overlapped with the first pad 121 and a first through electrode 161 vertically overlapped with the second pad 122 may have different widths in the horizontal direction. For example, a width in the horizontal direction of the first through electrode 161 vertically overlapped with the first pad 121 may be larger than the width in the horizontal direction of a first through electrode 161 vertically overlapped with the second pad 122.

In addition, the second through electrodes 162 may be provided in a plurality of numbers while being spaced apart from each other in the horizontal direction. At least one of the second through electrodes 162 may be vertically overlapped with the third pad 131. In addition, at least another one of the second through electrodes 162 may be vertically overlapped with the fourth pad 132.

At this time, a second through electrode 162 vertically overlapped with the third pad 131 and a second through electrode 162 vertically overlapped with the fourth pad 132 may have different widths in the horizontal direction. For example, a width in the horizontal direction of the second through electrode 162 vertically overlapped with the third pad 131 may be larger than the width in the horizontal direction of the second through electrode 162 vertically overlapped with the fourth pad 132.

Therefore, the embodiment may adjust the width in the horizontal direction of each through electrode based on the width in the horizontal direction of each pad. Through this, the embodiment can minimize a difference between the width of the through electrode and the width of the pad, and can minimize a signal transmission loss that may occur as the difference in the width increases. Through this, the embodiment can further improve the electrical characteristics of the circuit board and the semiconductor package including the same.

The first through electrode 161, the second through electrode 162, and the third through electrode 163 can be formed by filling an inside of the through hole penetrating each insulating layer with a conductive material. The through hole can be formed by any one of mechanical, laser, and chemical processing methods. The through hole can be formed by mechanical processing methods such as milling, drilling, and routing. In addition, the through hole can use a UV or CO2 laser method. In addition, the first through hole can use a chemical processing method using a chemical agent including minosilane, ketones, etc.

When the through hole is formed, the inside of the through hole may be filled with any one metal material selected from copper (Cu), silver (Ag), tin (Sn), gold (Au), nickel (Ni), and palladium (Pd), thereby forming the first through electrode 161, the second through electrode 162, and the third through electrode 163. At this time, the filling of the conductive material may utilize any one of electroless plating, electrolytic plating, screen printing, sputtering, evaporation, inkjetting, and dispensing, or a combination thereof.

The circuit board 100 of the embodiment includes a bump part disposed on a pad.

Specifically, the circuit board 100 of the embodiment may include a first bump 180 disposed on a first circuit layer 120. The first bump 180 may be disposed on the first pad 121 of the first circuit layer 120. The first bump 180 may be a post bump. The first bump 180 may be provided to improve electrical coupling with the semiconductor device and/or the external substrate.

That is, as a width of a terminal of the semiconductor device to be bonded to a circuit board and a pitch of the terminals are miniaturized, when the semiconductor device is mounted by a conductive adhesive such as solder, the conductive adhesive may diffuse, and thus a problem may occur in which a plurality of conductive adhesives are connected to each other. Through this, the embodiment may perform thermal compression bonding to reduce a volume of the conductive adhesive. At this time, if the first bump 180 is not provided in the circuit board, it may be difficult to reduce a volume of the conductive adhesive. This may be because a height of the electrode on which the conductive adhesive is disposed is lower than an upper surface of the first protective layer 170, and accordingly, a volume of the conductive adhesive increases by a difference between a height of the electrode and a height of the insulating layer.

Therefore, the embodiment may have a first bump 180 protruding above the first protective layer 170 to secure alignment with the terminal of the semiconductor device and diffusion prevention power to prevent the intermetallic compound (IMC) formed between the conductive adhesive and the electrode from diffusing into the circuit board.

Meanwhile, a second bump 190 may be provided at a lower surface of the second circuit layer 130. For example, the second bump 190 may be provided at a lower surface of the third pad 131 of the second circuit layer 130. The second bump 190 may have a structure corresponding to the first bump 180, and thus, a detailed description thereof will be omitted.

The first bump 180 and the second bump 190 may each have a certain level of thickness in the vertical direction. The thickness of each of the first bump 180 and the second bump 190 in the vertical direction may satisfy a range of 75 μm to 210 μm. For example, the thickness of each of the first bump 180 and the second bump 190 in the vertical direction may satisfy a range of 80 μm to 200 μm. For example, the thickness of each of the first bump 180 and the second bump 190 in the vertical direction may satisfy a range of 90 μm to 180 μm.

If the thickness of the first bump 180 and the second bump 190 in the vertical direction is less than 75 μm, the external substrate and/or semiconductor device may not be stably bonded on the first bump 180 and the second bump 190. Accordingly, the operating characteristics of the external substrate and/or the semiconductor device may be deteriorated. If the vertical thickness of the first bump 180 and the second bump 190 is less than 75 μm, the volume of the conductive adhesive such as the solder may not be reduced, and thus, physical reliability and/or electrical reliability problems may occur due to diffusion of the intermetallic compound. In addition, if the vertical thickness of the first bump 180 and the second bump 190 exceeds 210 μm, the rigidity of the bump may be deteriorated, and thus, reliability problems such as collapse of the semiconductor device and/or the external substrate when combined may occur. If the vertical thickness of the first bump 180 and the second bump 190 exceeds 210 μm, the thickness of the circuit board 100 and the thickness of the semiconductor package may increase.

The circuit board 100 of the embodiment may include a protective layer.

Specifically, a first protective layer 170 may be disposed on the first insulating layer 111. The first protective layer 170 may include at least one open region. Preferably, the first protective layer 170 may include a plurality of open regions.

The first protective layer 170 may include a first open region 171 vertically overlapping the first pad 121. The first open region 171 of the first protective layer 170 may open a portion of an upper surface of the first pad 121. For example, the first protective layer 170 may cover at least a portion of an upper surface of the first pad 121 and may include a first open region 171 that partially opens the upper surface of the first pad 121. The first open region 171 of the first protective layer 170 can expose a portion of the upper surface of the first pad 121 where the first bump 180 is to be disposed. Accordingly, the first open region 171 of the first protective layer 170 can be filled with the first bump 180.

The first protective layer 170 can include a second open region 172 vertically overlapping the second pad 122. The second open region 172 of the first protective layer 170 can open a portion of the upper surface of the second pad 122. For example, the second open region 172 of the first protective layer 170 may cover at least a portion of the upper surface of the second pad 122 and may include a second open region 172 that partially opens the upper surface of the second pad 122.

Specifically, each of the first open region 171 and the second open region 172 of the first protective layer 170 may be provided as a SMD (Solder Mask Defined type).

A planar area of the first open region 171 of the first protective layer 170 may be different from a planar area of the second open region 172. Preferably, a planar shape of the first open region 171 of the first protective layer 170 may be different from a planar shape of the second open region 172.

For example, the planar shape of the first open region 171 of the first protective layer 170 may have a snowflake shape including a plurality of protruding portions spaced apart from each other. Accordingly, a horizontal distance between the inner wall of the first open region 171 of the first protective layer 170 from a side surface of the first pad 121 may have different horizontal distances along an edge of the upper surface of the first pad 121. For example, a horizontal distance in a protruding portion of the first open region 171 of the first protective layer 170 may be smaller than a horizontal distance in a portion other than the protruding portion of the first open region 171 of the first protective layer 170.

The planar shape of the second open region 172 of the first protective layer 170 may be different from the planar shape of the first open region 171 of the first protective layer 170. For example, the planar shape of the second open region 172 of the first protective layer 170 may not have the protruding portion in the planar shape of the first open region 171. For example, the planar shape of the second open region 172 may be any one of a square shape, a circular shape, an oval shape, and a polygonal shape.

Meanwhile, a second protective layer 175 may be disposed under the second insulating layer 112. The second protective layer 175 may include a third open region 176 and a fourth open region 177. The third open region 176 of the second protective layer 175 may have a planar shape corresponding to the first open region 171 of the first protective layer 170. In addition, the fourth open region 177 of the second protective layer 175 may have a planar shape corresponding to the second open region 172 of the first protective layer 170.

Meanwhile, although the second protective layer 175 is described as including the third open region 176 and the fourth open region 177, the embodiment is not limited thereto. For example, the second protective layer 175 may include only the third open region 176 according to the embodiment, may include only the fourth open region 177, or may include both the third open region 176 and the fourth open region 177.

The first protective layer 170 and the second protective layer 175 may include an insulating material. The first protective layer 170 and the second protective layer 175 may include various materials that can be applied and then cured by heating to protect surfaces of the insulating layer and the circuit layer.

The first protective layer 170 and the second protective layer 175 may be solder resist layers containing organic polymer materials. For example, the first protective layer 170 and the second protective layer 175 may contain an epoxy acrylate series resin. In detail, the first protective layer 170 and the second protective layer 175 may contain a resin, a curing agent, a photo initiator, a pigment, a solvent, a filler, an additive, an acrylic series monomer, etc. However, the embodiment is not limited thereto, and the first protective layer 170 and the second protective layer 175 may be any one of a photo solder resist layer, a cover-lay, and a polymer material.

A thickness of the first protective layer 170 and a thickness of the second protective layer 175 may be 1 μm to 20 μm. The thicknesses of the first protective layer 170 and the second protective layer 175 may be 1 μm to 15 μm. For example, the thicknesses of the first protective layer 170 and the second protective layer 175 may be 5 μm to 20 μm. If the thickness of the first protective layer 170 and the second protective layer 175 exceeds 20 μm, the overall thickness of the circuit board and the semiconductor package may increase.

Hereinafter, the open regions provided in the first protective layer 170 and the second protective layer 175 according to the embodiment will be described.

However, the third open region 176 and the fourth open region 177 provided in the second protective layer 175 may correspond to the first open region 171 and the second open region 172 provided in the first protective layer 170. Therefore, the first open region 171 and the second open region 172 provided in the first protective layer 170 together with the first pad 121 and the second pad 122 of the first circuit layer 120 will be described below.

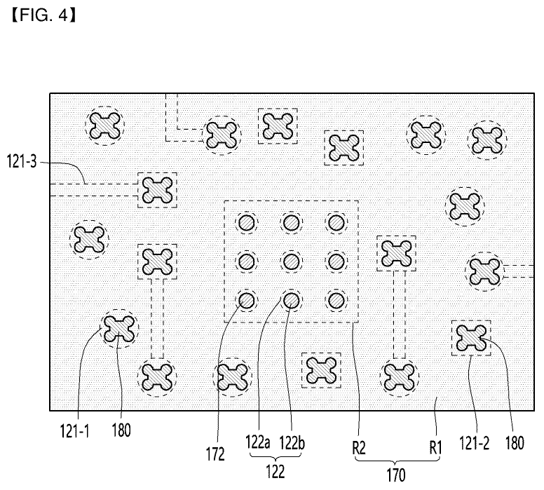

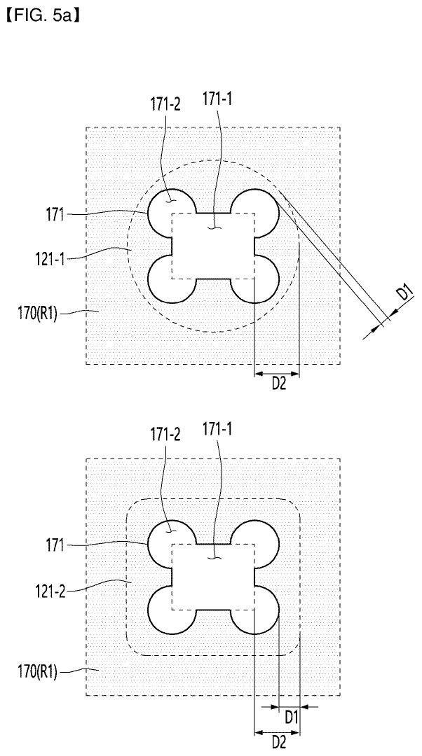

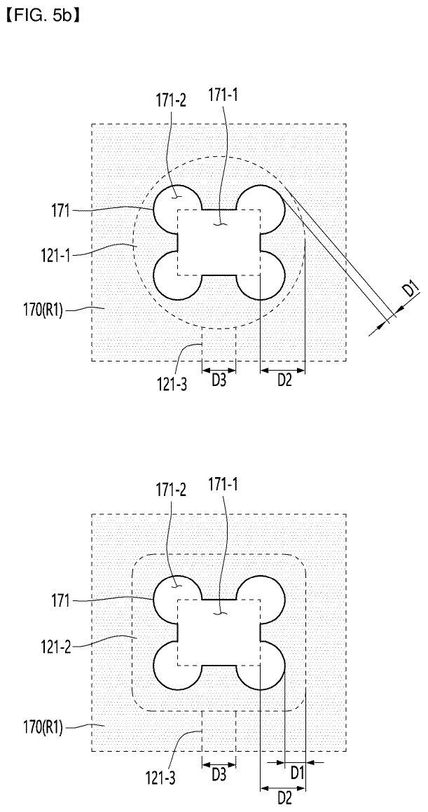

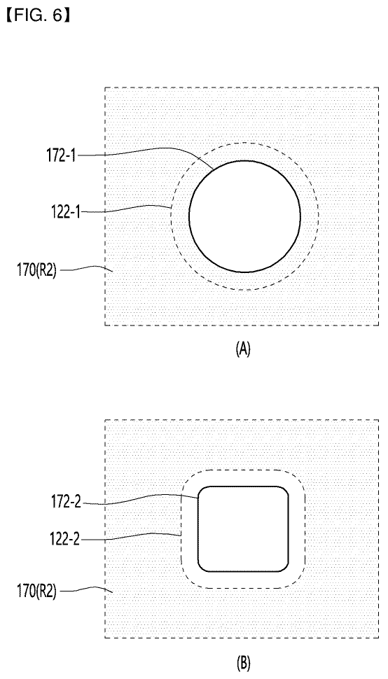

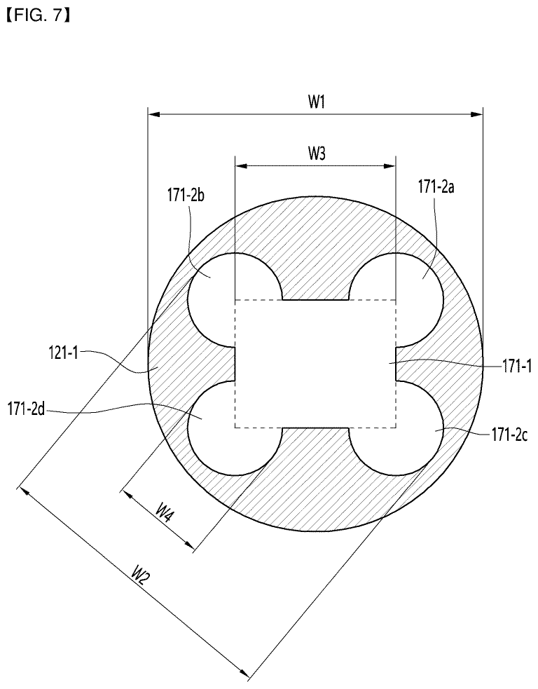

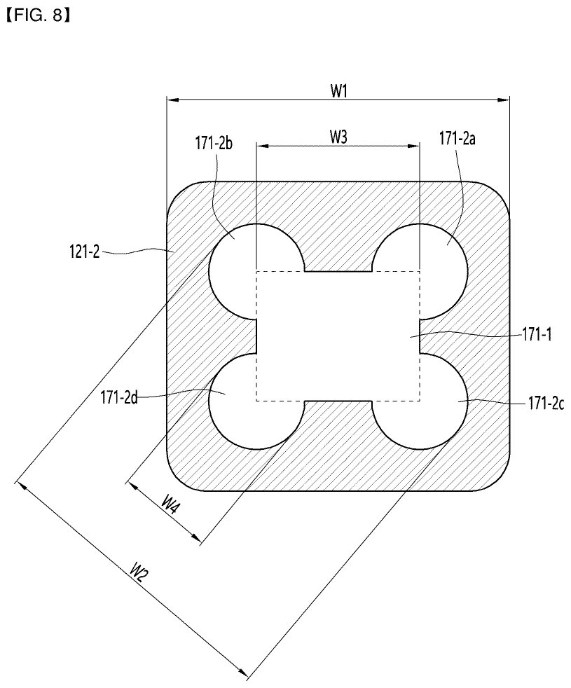

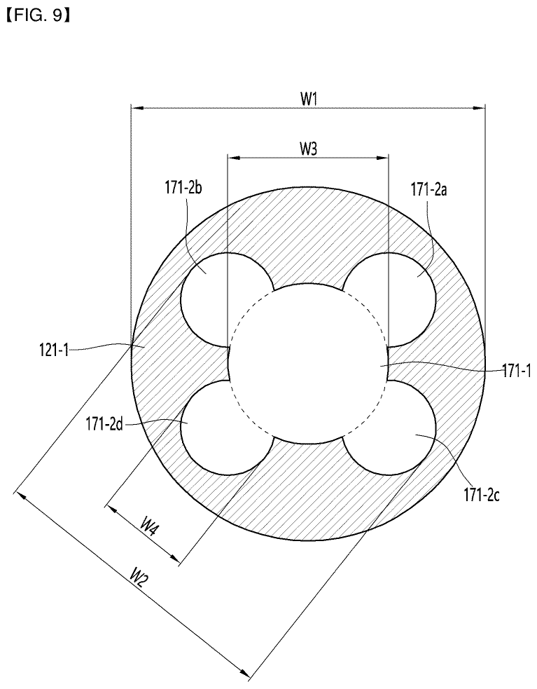

FIG. 3 is a plan view showing a state in which the first bump is removed from the circuit board of FIG. 2, FIG. 4 is a plan view showing a state in which the first bump is disposed from the circuit board of FIG. 2, FIG. 5a and FIG. 5b are drawings for explaining a first open region of a first protective layer according to an embodiment, FIG. 6 is a drawing for explaining a second open region of a first protective layer according to an embodiment, FIG. 7 is an enlarged view of a first open region provided on a first-first pad of an embodiment, FIG. 8 is an enlarged view of a first open region provided on a first-second pad of an embodiment, and FIG. 9 is a modified example of a first open region according to an embodiment.

Hereinafter, the first open region 171 and the second open region 172 provided in the first protective layer 170 of the embodiment will be described in detail with reference to FIGS. 3 to 9.

Referring to FIGS. 3 and 4, a first circuit layer 120 may be disposed on a first insulating layer 111.

The first circuit layer 120 may include a first pad 121 and a second pad 122. At this time, although not shown in the drawing, the first circuit layer 120 may include a trace connected to at least one of the first pad 121 and the second pad 122.

In addition, a first protective layer 170 may be disposed on the first insulating layer 111. At this time, the first protective layer 170 may include a first open region 171 and a second open region 172.

At this time, the first protective layer 170 may include a first region R1 and a second region R2. The first region R1 may mean an edge region of the first protective layer 170, but is not limited thereto. The first region R1 may mean a region of the first protective layer 170 vertically overlapping the first pad 121 of the first circuit layer 120. The second region R2 may mean a central region of the first protective layer 170, but is not limited thereto. The second region R2 may mean a region of the first protective layer 170 that vertically overlaps the second pad 122 of the first circuit layer 120.

In addition, the first open region 171 may be provided in the first region R1 of the first protective layer 170. In addition, the second open region 172 may be provided in the second region R2 of the first protective layer 170.

Meanwhile, each of the first pad 121 and the second pad 122 of the first circuit layer 120 may vertically overlap with the first open region 171 and the second open region 172 of the first protective layer 170.

For example, the first pad 121 may vertically overlap with the first open region 171 of the first protective layer 170. At this time, an upper surface of the first pad 121 may partially vertically overlap with the first open region 171 of the first protective layer 170. For example, the upper surface of the first pad 121 may include a portion covered by the first protective layer 170 and a portion exposed by vertically overlapping with the first open region 171.

At this time, an edge of the upper surface of the first pad 121 may not vertically overlap with the first open region 171 of the first protective layer 170. Preferably, the edge of the upper surface of the first pad 121 may be covered with the first protective layer 170. Therefore, the first open region 171 of the first protective layer 170 may partially expose a region of the upper surface of the first pad 121 that is spaced apart from the edge of the upper surface of the first pad 121.

For example, the second pad 122 may vertically overlap with the second open region 172 of the first protective layer 170. At this time, the upper surface of the second pad 122 may partially vertically overlap with the second open region 172 of the first protective layer 170. For example, the upper surface of the second pad 122 may include a portion covered with the first protective layer 170 and a portion exposed by vertically overlapping the second open region 172.

In addition, the edge of the upper surface of the second pad 122 may not vertically overlap the second open region 172 of the first protective layer 170. Preferably, the edge of the upper surface of the second pad 122 may be covered with the first protective layer 170. Therefore, the second open region 172 of the first protective layer 170 may partially expose a region of the upper surface of the second pad 122 that is separated from the edge of the upper surface of the second pad 122.

A width of the first pad 121 in the horizontal direction may satisfy a range of 70 μm to 110 μm. Preferably, the width of the first pad 121 in the horizontal direction can satisfy a range of 75 μm to 105 μm. More preferably, the width of the first pad 121 in the horizontal direction can satisfy a range of 80 μm to 100 μm. If the width of the first pad 121 in the horizontal direction is smaller than 70 μm, a contact area between the first pad 121 and the first bump 180 may decrease, and thus the physical bonding reliability between them may deteriorate. If the width of the first pad 121 in the horizontal direction is smaller than 70 μm, the first bump 180 may not be stably disposed on the first pad 121, and further, the semiconductor device and/or the external substrate may not be stably disposed on the first bump 180.

If the width in the horizontal direction of the first pad 121 is greater than 110 μm, a space occupied by the first pad 121 may increase, and thus an area of the circuit board and semiconductor package may increase. For example, if the width in the horizontal direction of the first pad 121 is greater than 110 μm, the first pads 121 may not all be disposed within a limited space, and thus the circuit integration may be reduced.

The width in the horizontal direction of the second pad 122 may be smaller than the width in the horizontal direction of the first pad 121. For example, a width in the horizontal direction of the second pad 122 may satisfy a range of 20 μm to 70 μm. Preferably, a width in the horizontal direction of the second pad 122 may satisfy a range of 25 μm to 65 μm. More preferably, the width in the horizontal direction of the second pad 122 may satisfy a range of 30 μm to 60 μm. If the width in the horizontal direction of the second pad 122 is less than 20 μm, the semiconductor device may not be stably disposed on the second pad 122. For example, if the width in the horizontal direction of the second pad 122 is less than 20 μm, the electrical connection reliability with the semiconductor device may deteriorate. If the width in the horizontal direction of the second pad 122 is greater than 70 μm, the second pads 122 may not all be disposed within a limited space. If the width in the horizontal direction of the second pad 122 is greater than 70 μm, a spacing between the plurality of second pads connected to the terminals of the semiconductor device may increase, and thus a signal transmission distance may increase. When the signal transmission distance increases, the signal transmission loss may increase in proportion to the signal transmission distance, and thus the electrical reliability may deteriorate. For example, if the width in the horizontal direction of the second pad 122 is greater than 70 μm, the operating characteristics of the semiconductor device may deteriorate.

Meanwhile, the planar shapes of the first pad 121 and the second pad 122 may be the same as each other, or may be different from each other.

For example, the first pad 121 may include a first-first pad 121-1 having a first planar shape. For example, the first-first pad 121-1 may have a planar shape of a circular or oval shape.

In addition, the first pad 121 may include a first-second pad 121-2 having a second planar shape. For example, the first-second pad 121-2 may have a planar shape of a square shape.

In addition, the second pad 122 may include a second-first pad 122-1 having a first planar shape. For example, the second-first pad 122-1 may have a planar shape of a circular or oval shape.

In addition, the second-second pad 122 may include a second-second pad 122-2 having a second planar shape. For example, the second-second pad 122-2 may have a planar shape of a square shape.

In addition, the first-first pad 121-1 may be selectively connected to a trace 121-3. In addition, the first-second pad 121-2 may be selectively connected to a trace 121-3. In addition, the second pad 122 may be selectively connected to the trace 121-3.

Meanwhile, the first open region 171 of the first protective layer 170 may have a planar shape different from the planar shape of the first pad 121. In addition, the first open region 171 of the first protective layer 170 may have a planar shape different from the planar shape of the second pad 122. In addition, the first open region 171 of the first protective layer 170 may have a planar shape different from the planar shape of the second open region 172 of the first protective layer 170.

Each of the first-first pad 121-1 and the first-second pad 121-2 of the first pad 121 may vertically overlap with the first open region 171 of the first protective layer 170. For example, each of the first-first pad 121-1 and the first-second pad 121-2 of the first pad 121 may partially vertically overlap with the first open region 171 of the first protective layer 170.

Each of the first-first pad 121-1 and the first-second pad 121-2 of the first pad 121 may include a non-overlapping region that does not vertically overlap with the first open region 171 of the first protective layer 170 and an overlapping region that vertically overlaps with the first open region 171.

For example, the first-first pad 121-1 of the first pad 121 may include a first portion 121a1 covered with the first protective layer 170. The first portion 121a1 of the first-first pad 121-1 of the first pad 121 may not vertically overlap with the first open region 171 of the first protective layer 170. The first portion 121a1 of the first-first pad 121-1 of the first pad 121 may be provided along an edge of an upper surface of the first-first pad 121-1. That is, an edge portion of the upper surface of the first-first pad 121-1 corresponding to the first portion 121a1 of the first-first pad 121-1 may be entirely covered by the first protective layer 170 and may not vertically overlap with the first open region 171.

In addition, the first-first pad 121-1 of the first pad 121 may include a second portion 121b1 that vertically overlaps with the first open region 171 of the first protective layer 170.

In addition, the first-second pad 121-2 of the first pad 121 may include a first portion 121a2 covered with the first protective layer 170. The first portion 121a2 of the first-second pad 121-2 of the first pad 121 may not vertically overlap with the first open region 171 of the first protective layer 170. The first portion 121a2 of the first-second pad 121-2 of the first pad 121 may be provided along an edge of an upper surface of the first-second pad 121-2. That is, an edge portion of the upper surface of the first-second pad 121-2 corresponding to the first portion 121a2 of the first-second pad 121-2 may be entirely covered by the first protective layer 170 and may not vertically overlap with the first open region 171.

In addition, the first-second pad 121-2 of the first pad 121 may include a second portion 121b2 that vertically overlaps with the first open region 171 of the first protective layer 170.

In addition, the second pad 122 may include a first portion 122a covered with the first protective layer 170. The first portion 122a of the second pad 122 may not vertically overlap with the second open region 172 of the first protective layer 170. The first portion 122a of the second pad 122 may be provided along an edge of an upper surface of the second pad 122. That is, an edge portion of the upper surface of the second pad 122 corresponding to the first portion 122a of the second pad 122 may be entirely covered by the first protective layer 170 and may not vertically overlap with the second open region 172.

In addition, the second pad 122 may include a second portion 122b that vertically overlaps with the second open region 172 of the first protective layer 170.

Meanwhile, the first bump 180 may be disposed on the first pad 121. For example, the first bump 180 may be disposed on the first portion 121a1 and 121a2 of each of the first-first pad 121-1 and the first-second pad 121-2 of the first pad 121. For example, the first bump 180 may be disposed in the first open region 171 of the first protective layer 170. Preferably, the first bump 180 may include a portion disposed in the first open region 171 of the first protective layer 170. A planar shape of the first bump 180 may correspond to a planar shape of the first open region 171 of the first protective layer 170. For example, the planar shape of the lower surface of the first bump 180 may correspond to the planar shape of the first open region 171 of the first protective layer 170. For example, the lower surface of the first bump 180 may have a planar shape including a plurality of protruding portions spaced apart from each other. For example, a lower surface of the first bump 180 may have a snowflake shape.

The planar shapes of the first open region 171 and the second open region 172 will be described in more detail as follows.

Referring to FIG. 5a, the first-first pad 121-1 and the first-second pad 121-2 of the first pad 121 may each have different planar shapes. At this time, the first-first pad 121-1 and the first-second pad 121-2 may not be directly connected to the trace 121-3. For example, the first-first pad 121-1 and the first-second pad 121-2 of FIG. 5a may mean pads that are not connected to the trace 121-3.

Referring to (A) of FIG. 5a, the planar shape of the first-first pad 121-1 of the first pad 121 may be a circular shape. In addition, referring to (B) of FIG. 5a, the planar shape of the first-second pad 121-2 of the first pad 121 may be a square shape.

At this time, the first protective layer 170 may include a first open region 171 that vertically overlaps the first-first pad 121-1 and the first-second pad 121-2, respectively. The planar shape of the first open region that vertically overlaps the first-first pad 121-1 may be the same as the planar shape of the first open region that vertically overlaps the first-second pad 121-2.

However, the embodiment is not limited thereto, and the planar shape of the first open region vertically overlapping the first-first pad 121-1 may be different from the planar shape of the first open region vertically overlapping the first-second pad 121-2. For example, the planar shape of the first open region vertically overlapping the first-second pad 121-2 may be as illustrated in (B) of FIG. 5. The planar shape of the first open region vertically overlapping the first-first pad 121-1 may be as illustrated in FIG. 9. For example, the first open region 171 may include a first part 171-1 and a second part 171-2 described below. For example, an inner surface forming the first open region 171 may have a first inner surface and a second inner surface having a step along the horizontal direction. In addition, the first inner surface may mean an inner surface of the first part 171-1, and the second inner surface may mean an inner surface of the second part 171-2.

In addition, the first part 171-1 of the first open region 171 may follow a shape of a pad that is vertically overlapped therewith. For example, the first part 171-1 of the first open region that is vertically overlapped with the first-first pad 121-1 may have a circular shape corresponding to the planar shape of the first-first pad 121-1. In addition, the first part 171-1 of the first open region that is vertically overlapped with the first-second pad 121-2 may have a square shape corresponding to the planar shape of the first-second pad 121-2.

Meanwhile, the first part 171-1 and the second part 171-2 of the first open region 171 may be connected to each other. That is, the second part 171-2 of the first open region 171 may be a portion protruding from the first part 171-1 in an outward direction. For example, the second part 171-2 of the first open region 171 may be a portion protruding or extending from the first part 171-1 toward an edge of the upper surface of the first pad 121. The second part 171-2 of the first open region 171 may be provided in a plurality of numbers. For example, the first open region 171 may include a first part 171-1 and a plurality of second parts 171-2 protruding from the first part 171-1 in an outward direction and spaced apart from each other.

Therefore, referring to (A) and (B) of FIG. 5a, a horizontal distance between an inner wall of the first open region 171 of the first protective layer 170 from a side surface of the first pad 121 may have different horizontal distances along an edge of the upper surface of the first pad 121. For example, a horizontal distance D1 in the second part 171-2 of the first open region 171 of the first protective layer 170 may be smaller than a horizontal distance D2 in the first part 171-1 of the first open region 171 of the first protective layer 170. For example, the first inner wall of the first part 171-1 of the first open region 171 and the second inner wall of the second part 171-2 may have a step in the horizontal direction. For example, the first inner wall of the first part 171-1 of the first open region 171 may be located further inward than the second inner wall of the second part 171-2. Conversely, the second inner wall of the second part 171-2 of the first open region 171 may be located further outward than the first inner wall of the first part 171-2. Here, a fact that the first inner wall and the second inner wall have a step may mean that an entire inner wall of the first open region 171 includes an outer portion that is relatively located outward, and an inner portion of a protruding surface that protrudes inward from the outer portion.

Meanwhile, referring to FIG. 5b, the first-first pad 121-1 and the first-second pad 121-2 may be connected to the trace 121-3.

The trace 121-3 may not vertically overlap with the first open region 171 of the first protective layer 170. Specifically, the trace 121-3 is connected to a side portion of the first-first pad 121-1 and/or the first-second pad 121-2. At this time, edge regions of uppers surface of the first-first pad 121-1 and the first-second pad 121-2 adjacent to side portions of the first-first pad 121-1 and the first-second pad 121-2 may not vertically overlap with the first open region 171 of the first protective layer 170. Accordingly, the trace 121-3 may not vertically overlap with the first open region 171 of the first protective layer 170.

A horizontal distance D3 between one side surface and the other side surface of the trace 121-3 may be determined by the width of the first-first pad 121-1 and the first-second pad 121-2 and the width of the open region 171 of the first protective layer 170. The horizontal distance D3 between one side surface and the other side surface of the trace 121-3 may mean the width D3 of the trace 121-3 in the horizontal direction. This will be described in more detail below.

Meanwhile, referring to FIG. 6, the inner wall of the second open region 172 of the first protective layer 170 may not have a step in the horizontal direction. For example, the second open region 172 of the first protective layer 170 may not include a protruding portion in the first open region 171.

For example, referring to (A) of FIG. 6, the second open region 172 of the first protective layer 170 may include a second-first open region 172-1 vertically overlapping the second-first pad 122-1 of the second pad 122. A planar shape of the second-first pad 122-1 of the second pad 122 may have a circular shape. Correspondingly, the planar shape of the second-first open region 172-1 may have a circular shape corresponding to the planar shape of the second-first pad 122-1 of the second pad 122.

For example, referring to (B) of FIG. 6, the second open region 172 of the first protective layer 170 may include a second-second open region 172-2 vertically overlapping the second-second pad 122-2 of the second pad 122. The planar shape of the second-second pad 122-2 of the second pad 122 may have a square shape. Correspondingly, the planar shape of the second-second open region 172-2 may have a square shape corresponding to the planar shape of the second-second pad 122-2 of the second pad 122.

At this time, inner walls of the second-first open region 172-1 and the second-second open region 172-2 of the first protective layer 170 may not have a step in the horizontal direction. For example, the second-first open region 172-1 and the second-second open region 172-2 of the first protective layer 170 may not include the second part 171-2 of the first open region 171. For example, the second-first open region 172-1 and the second-second open region 172-2 of the first protective layer 170 may include only the first part 171-1 of the first open region 171.

That is, a bump may not be disposed on the second pad 122. In addition, the second pad 122 may have a relatively smaller width than the first pad 121. Therefore, even if the inner wall of the second open region 172 vertically overlapping the second pad 122 does not have a step in the horizontal direction, it may not affect the bonding with the semiconductor device or the bonding with the bump.

However, the first bump 180 may be disposed on the first pad 121. Therefore, the first open region 171 vertically overlapping the first pad 121 may affect the bonding reliability with the first bump 180 and the bonding reliability with the external substrate and/or the semiconductor device.

For example, if the inner wall of the first open region 171 does not have a step in the horizontal direction, the reliability of the bonding between the first bump 180 and the first pad 121 may be reduced. For example, when an impact occurs from the outside, since the inner wall of the first open region 171 does not have a step, the impact may be simultaneously transmitted to the entire region of the first bump 180, which may cause a crack to occur in the first bump 180.

Unlike this, the inner wall of the first open region 171 of the embodiment may have a step in the horizontal direction. Accordingly, when an impact occurs from the outside, since the inner wall of the first open region 171 has a step, the impact may be transmitted only to a region located relatively outer among the entire region of the first bump 180, and the impact may not be transmitted to a region located relatively inner. For example, the embodiment may have the inner wall of the first open region 171 have a step, and may disperse the impact generated on the first bump 180 based on the step. Through this, the embodiment may improve the mechanical reliability and/or electrical reliability of the first bump 180, and may improve the mechanical reliability and/or electrical reliability between the circuit board and a semiconductor device and/or an external substrate.

To summarize, the first open region 171 may include a first part 171-1 and a second part 171-2 protruding outward from the first part 171-1. In addition, the inner wall of the first open region 171 may have a step in the horizontal direction according to the first part 171-1 and the second part 171-2. Therefore, the embodiment can disperse the physical impact applied to the first bump 180 based on the step of the inner wall of the first open region 171. That is, the embodiment can increase the resistance of the first bump 180 to mechanical stress by having the step of the inner wall of the first open region 171 in the horizontal direction, thereby improving the mechanical and/or physical reliability of the circuit board and the semiconductor package including the same.

Meanwhile, referring to FIGS. 7 and 8, the first open region 171 can include a first part 171-1 and a second part 171-2. The second parts 171-2 can be provided in multiple positions spaced apart from each other.

The first part 171-1 of the first open region 171 can have a square shape. The second part 171-2 may protrude outwardly from each of four corner portions of the first part 171-1.

For example, the second part 171-2 may include first to fourth sub-parts 171-2a, 171-2b, 171-2c, and 171-2d protruding outwardly from different positions of the first part 171-1.

At this time, an overall width of the first open region 171, a width of the first part 171-1, and a width of the second part 171-2 may be determined based on the width of the first pad 121.

Since a width W1 of the first pad 121 has already been described above, a detailed description thereof will be omitted. For example, if the first pad 121 has a circular shape corresponding to the first-first pad 121-1 of FIG. 7, the width W1 may mean the diameter of the first-first pad 121-1. For example, if the first pad 121 has a square shape corresponding the first-second pad 121-2 of FIG. 8, the width W1 may mean the width of the first-second pad 121-2 in the horizontal direction.

The first open region 171 may have a second width W2. The second width W2 may mean a width of a region having a largest width in an entire region of the first open region 171. For example, the second width W2 may mean a width between each end of two sub-parts facing each other of the second part 171-2.

Therefore, the second width W2 of the first open region 171 may mean a maximum width of the first open region 171.

The maximum width W2 of the first open region 171 may satisfy a range of 70% to 95% of the width W1 of the first pad 121. For example, the maximum width W2 of the first open region 171 may satisfy a range of 72% to 92% of the width W1 of the first pad 121. For example, the maximum width W2 of the first open region 171 may satisfy a range of 75% to 90% of the width W1 of the first pad 121.

If the maximum width W2 of the first open region 171 is less than 70% of the width W1 of the first pad 121, an area of the upper surface of the first pad 121 exposed through the first open region 171 may decrease. In addition, if the area of the exposed upper surface of the first pad 121 decreases, a contact area between the first pad 121 and the first bump 180 may decrease, and thus, the first bump 180 may peel off from the first pad 121. In addition, if the maximum width W2 of the first open region 171 is less than 70% of the width W1 of the first pad 121, the difference in width between the first bump 180 and the first pad 121 may increase, and thus, signal transmission loss may increase. In addition, if the maximum width W2 of the first open region 171 exceeds 95% of the width W1 of the first pad 121, at least a portion of the edge of the upper surface of the first pad 121 may be exposed through the first open region 171. For example, if the maximum width W2 of the first open region 171 exceeds 95% of the width W1 of the first pad 121, at least a portion of the side surface of the first pad 121 may not be covered by the first protective layer 170 due to a process error in a process of forming the first open region 171, and thus, mechanical reliability and/or electrical reliability problems may occur.

Meanwhile, the width W3 of the first part 171-1 of the first open region 171 can satisfy a range of 30% to 70% of the width W1 of the first pad 121. For example, the width W3 of the first part 171-1 of the first open region 171 can satisfy a range of 32% to 68% of the width W1 of the first pad 121. For example, the width W3 of the first part 171-1 of the first open region 171 can satisfy a range of 35% to 65% of the width W1 of the first pad 121.

If the width W3 of the first part 171-1 of the first open region 171 is less than 30% of the width W1 of the first pad 121, the contact area between the first bump 180 and the first pad 121 is reduced, and thus, mechanical reliability and/or physical reliability problems may occur. For example, if the width W3 of the first part 171-1 of the first open region 171 is less than 30% of the width W1 of the first pad 121, a region in which the width is rapidly reduced may be provided in the first bump 180, and thus, a crack may occur in the first bump 180.

If the width W3 of the first part 171-1 of the first open region 171 exceeds 70% of the width W1 of the first pad 121, a horizontal length of the step of the first open region 171 may decrease, and the effect of dispersing the mechanical stress by the step structure of the embodiment may be insufficient.

Meanwhile, a width W4 of each of the second parts 171-2 of the first open region 171 may satisfy a range of 5% to 30% of a width W1 of the first pad 121. For example, the width W4 of each of the second parts 171-2 of the first open region 171 may satisfy a range of 8% to 27% of the width W1 of the first pad 121. For example, the width W4 of each of the second parts 171-2 of the first open region 171 can satisfy a range of 10% to 20% of the width W1 of the first pad 121.

If the width W4 of each of the second parts 171-2 of the first open region 171 is less than 5% of the width W1 of the first pad 121, the horizontal length of the step of the first open region 171 by the second parts 171-2 may decrease, and thus the effect of dispersing the mechanical stress by the step structure of the embodiment may be insufficient. If the width W4 of each of the second parts 171-2 of the first open region 171 exceeds 30% of the width W1 of the first pad 121, the second parts 171-2 may vertically overlap the edge of the upper surface of the first pad 121 due to a process error. In addition, if the width W4 of each of the second parts 171-2 of the first open region 171 exceeds 30% of the width W1 of the first pad 121, the width W3 of the first part 171-1 may decrease accordingly, thereby deteriorating the mechanical reliability and/or physical reliability between the first pad 121 and the first bump 180.

Meanwhile, it has been described that the first part 171-1 may have a square shape and the second part 171-2 may have a circular shape, but the embodiment is not limited thereto. For example, referring to FIG. 9, the first part 171-1 and the second part 171-2 may each have a circular shape, and the inner wall of the first open region 171 may have a step in the horizontal direction by controlling the width between the first part 171-1 and the second part 171-2.

However, the inner wall of the second part 171-2 is located outside the first part 171-1, and may be a part to which external mechanical stress is first transmitted. At this time, if the second part 171-2 has a square shape with an edge that is not a circular planar shape, stress may be concentrated on the edge portion, and as a result, the effect of dispersing the mechanical stress due to the step may be reduced. Therefore, it is preferable that the planar shape of the second part 171-2 has a circular shape, and the first part 171-1 may be deformed into various shapes such as a circular, oval, square, triangular, and polygonal shape.

Meanwhile, when the first circuit layer 120 is provided with a trace 121-3 and the first pad 121 is connected to the trace 121-3, a width D3 of the trace 121-3 may be determined by a width of the first open region 171 of the first protective layer 170. Conversely, when the trace 121-3 is provided, a width of the first open region 171 of the first protective layer 170 may be determined based on a width D3 of the trace 121-3.

The width D3 of the trace 121-3 may be smaller than the width W3 of the first part 171-1 of the first open region 171. If the width D3 of the trace 121-3 is greater than the width W3 of the first part 171-1 of the first open region 171, a ratio of the width of the trace 121-3 to the width of the first pad 121 may significantly increase, and thus, a transmission loss of the signal transmitted through the first pad 121 and the trace 121-3 may increase. Furthermore, if the width of the trace 121-3 is greater than the width W3 of the first part 171-1 of the first open region 171, an area occupied by the trace 121-3 on the first insulating layer 111 may increase, and thus, it may be difficult to thin the circuit board.

The width D3 of the trace 121-3 may be smaller or larger than the width W4 of the second part 171-2 of the first open region 171. For example, the width D3 of the trace 121-3 may be 50% or more of the width W4 of the second part 171-2 of the first open region 171. For example, the width D3 of the trace 121-3 may be 55% or more of the width W4 of the second part 171-2 of the first open region 171. For example, the width D3 of the trace 121-3 may be 60% or more of the width W4 of the second part 171-2 of the first open region 171. If the width D3 of the above trace 121-3 is less than 50% of the width W4 of the second part 171-2 of the first open region 171, the width of the trace 121-3 may be significantly smaller than the width of the first pad 121, and signal transmission loss due to the difference in the width of the first pad 121 and the trace 121-3 may increase. If the width D3 of the trace 121-3 is less than 50% of the width W4 of the second part 171-2 of the first open region 171, the area occupied by the second part 171-2 in the first open region 171 of the first protective layer 170 may increase, and thus, a problem may occur in which at least a portion of the edge region of the upper surface of the first pad 121 vertically overlaps the first open region 171 of the first protective layer 170. If the width D3 of the trace 121-3 is less than 50% of the width W4 of the second part 171-2 of the first open region 171, the width W4 of the second part 171-2 may become larger than the width W3 of the first part 171-1 of the first open region 171, and thus, an exposed area of the upper surface of the first pad 121 may decrease. In addition, when the exposed area decreases, the semiconductor device may not be stably bonded onto the first pad 121, and thus, the semiconductor device may not operate stably or the operating characteristics of the semiconductor device may deteriorate. For example, when the width W4 of the second part 171-2 of the first open region 171 of the first protective layer 170 is 5 μm to 10 μm, the width D3 of the trace 121-3 may be greater than 2.5 μm to 5 μm.

Meanwhile, the width D3 of the trace 121-3 may be greater than ⅓ of a value of ½ of the difference between the width W3 of the first part 171-1 of the first open region 171 and the width W1 of the first pad 121. For example, the width D3 of the trace 121-3 may be greater than ⅓ of a horizontal distance D2 from the side surface of the first pad 121 to the inner wall of the first part 171-1 of the first open region 171 of the first protective layer 170. If the width D3 of the trace 121-3 is less than ⅓ of the horizontal distance D2 from the side surface of the first pad 121 to the inner wall of the first part 171-1 of the first open region 171 of the first protective layer 170, a plane area of the first pad 121 that vertically overlaps the first open region 171 may be out of a reference range. For example, if the planar area of the first pad 121 exceeds the reference range, an electrical and/or physical reliability problem may occur due to the edge region of the upper surface of the first pad 121 being exposed from the first open region 171. In addition, if the planar area of the first pad 121 is smaller than the reference range, a contact area between the first pad 121 and the solder, which is a conductive adhesive, may decrease, and thus the bonding strength between the first pad 121 and the semiconductor device may deteriorate.

The circuit board of the embodiment may include a first protective layer including a first pad and a first open region vertically overlapping the first pad. The inner wall of the first open region of the first protective layer may have a step along a horizontal direction. For example, the first open region of the first protective layer may include a first part and a second part protruding from the first part in an outward direction. The second parts may be provided in a plurality of numbers and may each protrude from different positions of the first part. The first open region of the first protective layer may include an inner wall of the first part and an inner wall of the second part, and the inner wall of the first part and the inner wall of the second part may have a step along a horizontal direction.

Accordingly, the embodiment may improve the bonding reliability of the first pad and the first bump, and further improve the bonding reliability with an external substrate and/or a semiconductor device.

For example, if the inner wall of the first open region does not have a step in the horizontal direction, the joint reliability between the first bump and the first pad may be deteriorated. For example, when an impact occurs from the outside, since the inner wall of the first open region does not have a step, the impact may be simultaneously transmitted to the entire region of the first bump, which may cause a crack to occur in the first bump.

In contrast, the inner wall of the first open region of the embodiment may have a step in the horizontal direction. Accordingly, when an impact occurs from the outside, since the inner wall of the first open region has a step, the impact may be transmitted only to a region located relatively outer among the entire region of the first bump, and the impact may not be transmitted to a region located relatively inner. For example, the embodiment may allow a step to be provided on the inner wall of the first open region, and may disperse the impact occurring in the first bump based on the step. Through this, the embodiment can improve the mechanical reliability and/or electrical reliability of the first bump, and thereby improve the mechanical reliability and/or electrical reliability between the circuit board and the semiconductor device and/or the external substrate.

### Semiconductor Package

Hereinafter, a semiconductor package according to an embodiment will be described.

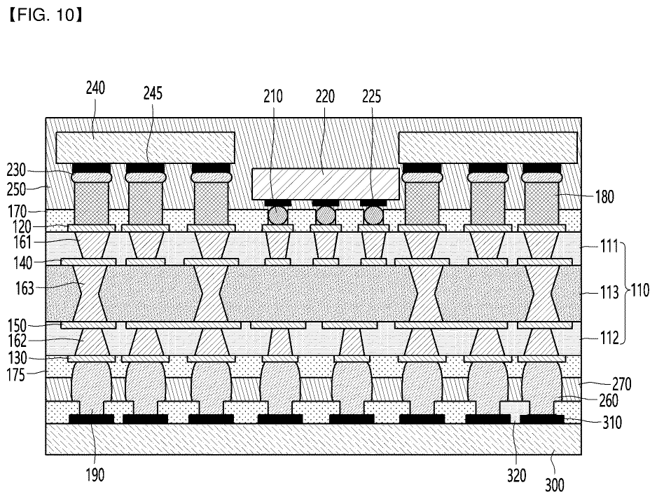

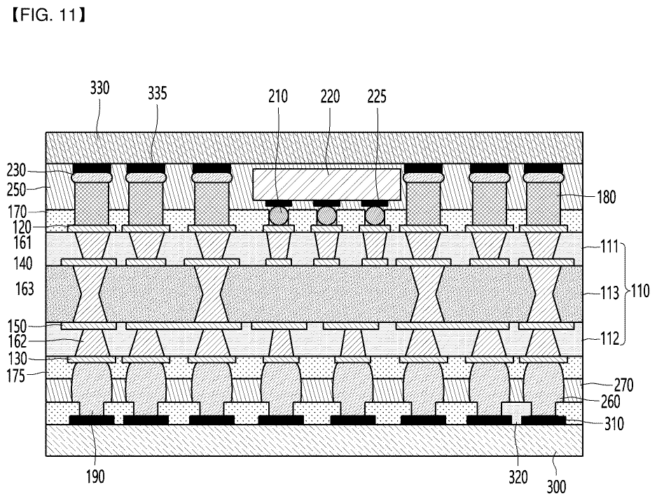

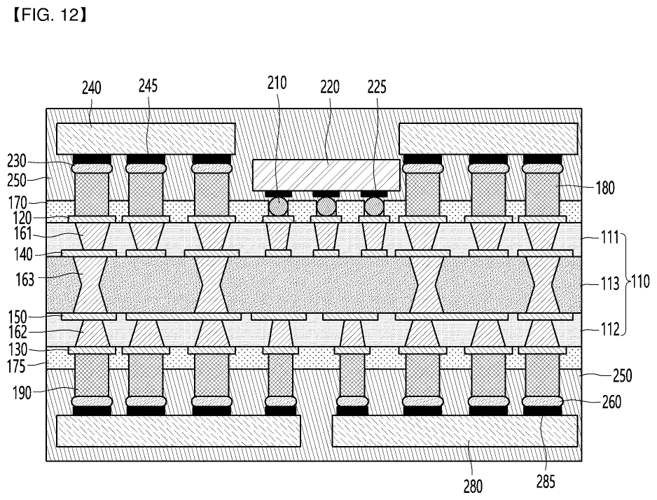

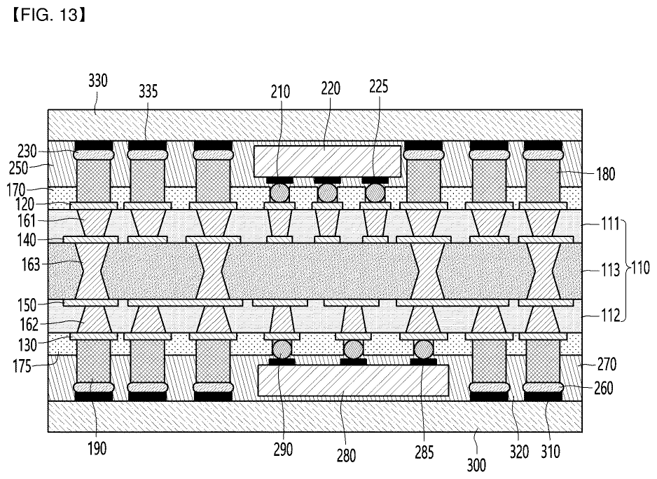

FIG. 10 is a drawing showing a semiconductor package according to a first embodiment, FIG. 11 is a drawing showing a semiconductor package according to a second embodiment, FIG. 12 is a drawing showing a semiconductor package according to a third embodiment, and FIG. 13 is a drawing showing a semiconductor package according to a fourth embodiment.

Referring to FIG. 10, the semiconductor package includes a circuit board.

In addition, the semiconductor package may include a first connection portion 210 disposed on a second pad 122 of a first circuit layer 120 of the circuit board.

The first connection portion 210 may include a spherical shape. For example, a cross-section of the first connection portion 210 may include a circular shape or a semicircular shape. For example, a cross-section of the first connection portion 210 may include a partially or entirely rounded shape. For example, a cross-sectional shape of the first connection portion 210 may be flat at one side and curved at the other side.

The semiconductor package may include a first semiconductor device 220 disposed on the first connection portion 210. The first semiconductor device 220 includes a terminal 225. The terminal 225 of the first semiconductor device 220 may be electrically coupled to the second pad 122 through the first connection portion 210. The first semiconductor device 220 may include a logic chip. For example, the first semiconductor device 220 may include an application processor chip. For example, the first semiconductor device 220 may include an analog-to-digital converter or an application-specific IC (ASIC). For example, the first semiconductor device 220 may include a memory chip. The memory chip may be a stack memory such as HBM. For example, the memory chip may include volatile memory (e.g., DRAM), non-volatile memory (e.g., ROM), flash memory, etc. In addition, the first semiconductor device 220 may include at least one of a drive IC chip, a diode chip, a power IC chip, a touch sensor IC chip, a multi-layer ceramic condenser (MLCC) chip, a ball grid array (BGA) chip, and a chip capacitor.

In addition, the semiconductor package may include a second connection portion 230 disposed on the first bump 180. At least one second semiconductor device 240 may be disposed on the second connection portion 230. For example, a terminal 245 of the at least one second semiconductor device 240 may be electrically coupled to the first bump 180 through the second connection portion 230.

In addition, the semiconductor package may further include a first molding member 250. The first molding member 250 can mold the first semiconductor device 220 and the second semiconductor device 240. In addition, the first molding member 250 can mold the first bump 180.

The first molding member 250 can have a low permittivity to enhance heat dissipation characteristics. For example, the permittivity (Dk) of the first molding member 250 can be 0.2 to 10. For example, the permittivity (Dk) of the first molding member 250 can be 0.5 to 8. For example, the permittivity (Dk) of the first molding member 250 can be 0.8 to 5. Accordingly, in the embodiment, the first molding member 250 has a low permittivity to enhance heat dissipation characteristics of the first and second semiconductor devices.

Meanwhile, the semiconductor package may include a third connection portion 260. At this time, the second bump 190 may not be provided on the lower surface of the second circuit layer 130 of the semiconductor package. In addition, the third connection portion 260 may also perform a function of the second bump 190.

A first external substrate 300 may be coupled under the third connection portion 260. The first external substrate 300 may include at least one external pad 310 and an external protective layer 320 including an open region vertically overlapping the external pad 310. The first external substrate 300 may be a main board of an electronic device. In another embodiment, the first external substrate 300 may be a separate package. For example, the first external substrate 300 may be a memory package. For example, the first external substrate 300 may be an interposer connected to a memory substrate on which a memory device is disposed. Alternatively, the first external substrate 300 may be a memory substrate.

In addition, the semiconductor package may include a second molding member 250 disposed between the circuit board and the first external substrate 300. The second molding member 250 may mold the third connection portion 260.

Meanwhile, referring to FIG. 11, the semiconductor package of the second embodiment may have a second external substrate 330 coupled to the second connection portion 230 instead of at least one second semiconductor device compared to the semiconductor package of the first embodiment. The second external substrate 330 may include at least one external pad 335, and the external pad 335 may be electrically coupled to the first bump 180 through the second connection portion 230.

Meanwhile, referring to FIG. 12, the semiconductor package of the third embodiment may include a second bump 190 disposed under the second circuit layer 130 compared to the semiconductor package of the first embodiment. In addition, the third connection portion 260 may be disposed under the second bump 190. At this time, at least one third semiconductor device 280 may be coupled to the third connection portion 260. For example, the terminal 285 of the at least one third semiconductor device 280 may be electrically coupled to the second bump 190 through the third connection portion 260. Meanwhile, a first external substrate 300 may be coupled to the third connection portion 260 instead of the third semiconductor device 280.

Meanwhile, referring to FIG. 13, the semiconductor package of the fourth embodiment may have a structure in which at least one third semiconductor device and the first external substrate are all coupled, compared to the semiconductor package of the third embodiment.

For example, the semiconductor package may have an external pad 310 of the first external substrate 300 coupled to a third connection portion 260 disposed under the second bump 190. In addition, the semiconductor package may include a fourth connection portion 290 disposed under the fourth pad 132 of the second circuit layer 130. A terminal 285 of at least one third semiconductor device 280 may be coupled to the fourth connection portion 290.

On the other hand, when the circuit board having the above-described characteristics of the invention is used in an IT device or home appliance such as a smart phone, a server computer, a TV, and the like, functions such as signal transmission or power supply can be stably performed. For example, when a circuit board having the features of the present invention performs a semiconductor package function, the circuit board can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transportation device and the circuit board to which the present invention is applied can achieve functional integrity or technical interlocking with each other.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1. A circuit board comprising:
a build up insulating layer including a plurality of insulating layers stacked along a vertical direction;
a pad part disposed on the build-up insulating layer; and,
a protective layer disposed on the pad part and including an open region overlapping the pad part along the vertical direction,
wherein an upper surface of the build-up insulating laver includes an inner region. and an edge region provided surrounding the inner region and provided along an edge of the upper surface of the build-up insulation layer,
wherein the pad part includes a first pad disposed in the edge region, and a second pad disposed in the inner region.
wherein the protective laver includes a first open region overlapping the first pad along the vertical direction, and a second open region overlapping the second pad along the vertical direction.
wherein the first open region and the second open region have different planar shapes, and
wherein the first open region includes a first part, and a second part including a plurality of sub-parts protruding from the first part toward the edge of the upper surface of the first pad and spaced apart from each other.

2. The circuit board of claim 1, wherein the first open region of the protective layer includes a first inner wall formed by the first part; and a second inner wall formed by the second part, and
wherein the first inner wall and the second inner wall have a step.

3. The circuit board of claim 2, wherein the step includes a plurality of steps corresponding to the plurality of sub-parts of the second part based on the first inner wall.

4. The circuit board of claim 1, wherein the first part and the second part have a same planar shape.

5. The circuit board of claim 1, wherein the first pad has a same planar shape as planar shapes of the first part and the second part.

6. The circuit board of claim 1, wherein the first part and the second part have different planar shapes.

7. The circuit board of claim 1, wherein the first part and the second part of the first open region do not overlap with the edge of the upper surface of the first pad along the vertical direction.

8. The circuit board of claim 1, further comprising:
a first bump disposed on a first pad vertically overlapping the first open region, and
wherein a lower surface of the first bump has a planar shape corresponding to a planar shape of the first open region.

9. The circuit board of claim 1, wherein a width in the horizontal direction of a region having a maximum width in the first open region satisfies a range of 70% to 90% of the width of the first pad in the horizontal direction.

10. The circuit board of claim 9, wherein a width of the first part of the first open region in the horizontal direction satisfies a range of 30% to 70% of the width of the first pad in the horizontal direction, and
wherein a width of the second part of the first open region in the horizontal direction satisfies a range of 5% to 30% of the width of the first pad in the horizontal direction.

11. The circuit board of claim 10, wherein a width of the second pad in the horizontal direction is smaller than the width of the first pad in the horizontal direction, and
wherein a width of the second open region in the horizontal direction is smaller than the width of the second pad in the horizontal direction.

12. The circuit board of claim 11, wherein an inner wall of the first open region has a step in the horizontal direction, and
wherein an inner wall of the second open region does not have a step in the horizontal direction.

13. The circuit board of claim 12, wherein the second open region and the second pad have a same planar shape.

14. The circuit board of claim 1, wherein the first pad includes a first-first pad and a first-second pad having different planar shapes, and
wherein the first open region includes a first open portion overlapping the first-first pad along the vertical direction, and a second open portion overlapping the first-second pad along the vertical direction.

15. The circuit board of claim 14, wherein the first open portion and the second open portion have a same planar shape,
wherein a first part of the first open portion and the first-first pad have different planar shapes, and
wherein a first part of the second open portion and the first-second pad have a same planar shape.

16. The circuit board of claim 15, wherein the planar shapes of the first part of the first open portion and the first part of the second open portion are different from planar shapes of the second part of the first open portion and the second part of the second open portion.

17. The circuit board of claim 14, wherein the first open portion and the second open portion have different planar shapes.

18. The circuit board of claim 17, wherein a first part of the first open portion and the first-first pad have the same planar shape, and
wherein a first part of the second open portion and the first-second pad have a same planar shape.

19. The circuit board of claim 18, wherein a planar shape of a second part of the first open portion is same as the planar shape of the first part of the first open portion, and
wherein a planar shape of a second part of the second open portion is different from the planar shape of the first part of the second open portion.

20. The circuit board of claim 1, further comprising:
a semiconductor device disposed on the second pad.
